(19) United States
(12) Patent Application Publication
(10) Pub. No.: US 2024/0355861 A1
(43) Pub. Date: Oct. 24, 2024

(54) IMAGE SENSOR AND IMAGE SENSOR PACKAGE

(71) Applicant: SAMSUNG ELECTRONICS CO., LTD., SUWON-SI (KR)

(72) Inventor: Dusik JUNG, Suwon-si (KR)

(21) Appl. No.: 18/382,205

(22) Filed: Oct. 20, 2023

(30) Foreign Application Priority Data
Apr. 21, 2023 (KR) 10-2023-0052831

(51) Int. Cl. H01L 27/146

(52) U.S. Cl. CPC H01L 27/14636; H01L 27/14603; H01L 27/14634

(57) ABSTRACT

An image sensor includes: a first structure including a first side, a second side opposite to the first side, a pixel region where a plurality of pixels are disposed, and a penetration electrode region disposed adjacent to the pixel region; a second structure in which a driving circuit for driving the plurality of pixels is disposed, and stacked on the second side of the first structure; a plurality of penetration electrodes that penetrate the first structure and the second structure to electrically connect the first structure and the second structure to each other, and are disposed in the penetration electrode region; and a protective layer that is disposed on the plurality of penetration electrodes, and divided into a plurality of cells, wherein the protective layer covers the penetration electrode region.

### CROSS-REFERENCE TO RELATED APPLICATION

This application claims priority under 35 U.S.C. § 119 to Korean Patent Application No. 10-2023-0052831 filed in the Korean Intellectual Property Office on Apr. 21, 2023, the disclosure of which is incorporated by reference herein in its entirety.

### TECHNICAL FIELD

The present inventive concept relates to an image sensor package, and more particularly to, an image sensor package including an image sensor.

### DISCUSSION OF THE RELATED ART

Generally, an image sensor is an electronic component that detects the intensity and color of an optical image, converts it into digital image data, and enables storage, transmission, and reproduction of images. Image sensors are typically incorporated into, for example, digital cameras, smartphones, automobiles, security devices, and robots.

An image sensor (e.g., a chip) is mounted on a device in the form of an image sensor package to protect the image sensor, prevent external materials from penetrating an image region of the image sensor, and enable power supplying and signal output between the image sensor and substrate.

In addition, in the case of an image sensor having a stacked structure in which two semiconductor substrates are stacked on each other, a penetration electrode may be provided to electrically connect the two semiconductor substrates to each other, and a protective layer to protect the penetration electrode may be formed on an exposed surface of the penetration electrode.

When the image sensor of the stacked structure is manufactured in the form of a package, a bonding structure (e.g., adhesive) for bonding a glass substrate over the image sensor may be disposed while being overlapped with the aforementioned protective layer. In this case, the protective layer may be disposed between the semiconductor substrate and the bonding structure, and due to a difference in coefficient of thermal expansion (CTE) between the protective layer and the semiconductor substrate, cracks may occur in the protective layer or the protective layer may be broken.

### SUMMARY

According to an embodiment of the present inventive concept, an image sensor includes: a first structure including a first side, a second side opposite to the first side, a pixel region where a plurality of pixels are disposed, and a penetration electrode region disposed adjacent to the pixel region; a second structure in which a driving circuit for driving the plurality of pixels is disposed, and stacked on the second side of the first structure; a plurality of penetration electrodes that penetrate the first structure and the second structure to electrically connect the first structure and the second structure to each other, and are disposed in the penetration electrode region; and a protective layer that is disposed on the plurality of penetration electrodes, and divided into a plurality of cells, wherein the protective layer covers the penetration electrode region.

According to an embodiment of the present inventive concept, an image sensor package includes: an image sensor including a substrate structure including a pixel region and a penetration electrode region, wherein a plurality of pixels are disposed in the pixel region, and the penetration electrode region is disposed adjacent to the pixel region, and wherein the image sensor further includes a protective layer that covers the penetration electrode region on the substrate structure; and a bonding structure that is disposed on the image sensor and at least partially surrounds the pixel region while overlapping at least a part of the penetration electrode region, wherein a plurality of penetration electrodes are disposed in the penetration electrode region, and extend a predetermined depth into the substrate structure from a surface of the substrate structure, wherein the protective layer is divided into a plurality of separated cells and cover surfaces of the plurality of penetration electrodes, and at least a part of the plurality of cells is disposed between the bonding structure and the substrate structure.

According to an embodiment of the present inventive concept, an image sensor package includes: an image sensor including a pixel region, a penetration electrode region, a substrate structure, and a protective layer, wherein a plurality of pixels are disposed in the pixel region, wherein the penetration electrode region disposed adjacent to the pixel region, wherein the substrate structure includes a first structure and a second structure, wherein the first structure has a plurality of pixels disposed in an upper portion of the first structure, wherein the second structure has a driving circuit for driving the plurality of pixels, and wherein the protective layer covers the penetration electrode region; a transparent substrate that is disposed above the image sensor; and a bonding structure that is disposed between the image sensor and the transparent substrate, and at least partially surrounds the pixel region, wherein the bonding structure partially overlaps at least a part of the penetration electrode region, wherein a plurality of penetration electrodes are disposed in the penetration electrode region, and extend a predetermined depth into the second structure while penetrating the first structure from a surface of the first structure, and wherein the protective layer is divided into a plurality of cells and cover surfaces of the plurality of penetration electrodes, and at least a part of the plurality of cells is disposed between the bonding structure and the first structure.

### BRIEF DESCRIPTION OF THE DRAWINGS

FIG. 1 is a cross-sectional view of an image sensor package according to an embodiment of the present inventive concept.

FIG. 2 is a cross-sectional view of FIG. 1, taken along the direction A-A.

FIG. 3 is a schematic cross-sectional view of an image sensor in an image sensor package according to an embodiment of the present inventive concept.

FIG. 4 is an enlarged view of the portion C of FIG. 1.

FIG. 5 is a schematic top plan view of the penetration electrode region in the image sensor package according to an embodiment of the present inventive concept.

FIG. 6 to FIG. 9 show various forms of FIG. 5.

FIG. 10 is a cross-sectional view of an image sensor package according to an embodiment of the present inventive concept.

### DETAILED DESCRIPTION OF THE EMBODIMENTS

Hereinafter, with reference to the accompanying drawing, embodiments of the present inventive concept will be described in detail. The present inventive concept may be implemented in many different forms and is not limited to the embodiments described herein.

Like reference numerals may designate like elements throughout the specification and drawings, and thus their descriptions may be omitted.

In the drawings, various thicknesses, lengths, and angles are shown and while the arrangement shown does indeed represent an embodiment of the present inventive concept, it is to be understood that modifications of the various thicknesses, lengths, and angles may be possible within the spirit and scope of the present inventive concept and the present inventive concept is not necessarily limited to the particular thicknesses, lengths, and angles shown.

Throughout this specification and the claims that follow, when it is described that an element is “coupled or connected” to another element, the element may be “directly coupled or connected” to the other element or “indirectly coupled or connected” to the other element through a third element.

It will be understood that when an element such as a layer, film, region, or substrate is referred to as being “on” another element, it can be directly on the other element or intervening elements may also be present. In contrast, when an element is referred to as being “directly on” another element, there are no intervening elements present between the element and the other element. Further, throughout the specification, the word “on” a target element will be understood to mean positioned above or below the target element, and will not necessarily be understood to mean positioned “at an upper side” based on an opposite direction to gravity direction.

Further, throughout the specification, the phrase “on a plane” means viewing a target portion from the top unless indicated otherwise, and the phrase “on a cross-section” means viewing a cross-section formed by vertically cutting a target portion from the side.

Hereinafter, an image sensor package according to various embodiments of the present inventive concept will be described with reference to the drawings.

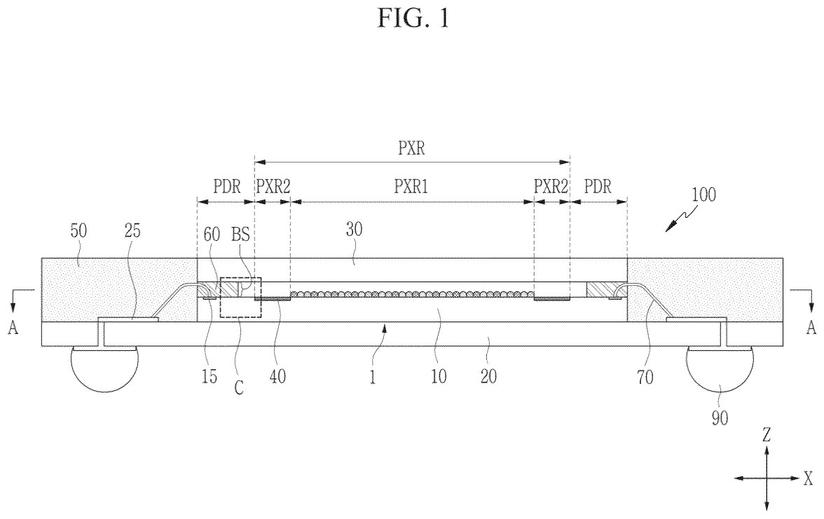

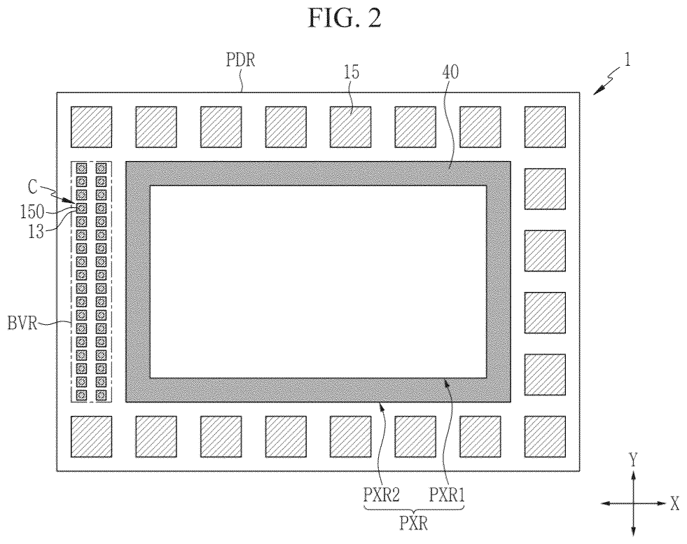

FIG. 1 is a cross-sectional view of an image sensor package according to an embodiment of the present inventive concept, and FIG. 2 is a cross-sectional view of FIG. 1, taken along the direction A-A. In FIG. 2, an image sensor 1 in an image sensor package according to an embodiment of the present inventive concept is illustrated for convenience in description and better understanding.

Referring to FIG. 1, an image sensor package 100 according to an embodiment of the present inventive concept may include an image sensor 1 and a bonding structure BS. In addition, the image sensor package 100 may include a transparent substrate 30 that covers the image sensor 1 on the bonding structure BS, and may further include a package substrate 20 that supplies or provides the image sensor 1.

As a semiconductor element that converts externally collected line to an electrical signal, the image sensor 1 may include a CMOS image sensor.

Referring to FIG. 1 and FIG. 2, the image sensor 1 may include a top surface and a bottom surface that oppose to each other (e.g., the top surface and the bottom surface are defined along the Z direction in FIG. 1). The image sensor 1 may include, on a plane, a central pixel region PXR and a peripheral region PDR at least partially surrounding the pixel region PXR.

Referring to FIG. 2, a penetration electrode region BVR may be disposed around or adjacent to the pixel region PXR. The penetration electrode region BVR is a region where a plurality of penetration electrodes 150 are disposed, and may be disposed in the peripheral region PDR. The configuration of the plurality of penetration electrodes 150 will be described later.

In FIG. 2, the penetration electrode region BVR is illustrated as being disposed on one side of the pixel region PXR, but the present inventive concept is not limited thereto. For example, the penetration electrode region BVR may be disposed in a random portion along the periphery of the pixel region PXR. For example, the penetration electrode region BVR may be disposed at opposite sides or adjacent sides of the pixel region PXR.

The peripheral region PDR may be a portion other than the pixel region PXR. A circuit for processing power, a control signal of the image sensor, and/or a pixel signal and the like obtained by the image sensor and wiring for connecting the circuit may be disposed in the peripheral region PDR.

A plurality of chip pads 15 may be disposed in the peripheral region PDR. The plurality of chips pad 15 may be disposed along the periphery of the pixel region PXR, and may be exposed through the top surface of the image sensor 1.

The plurality of chip pads 15 may be electrically connected with a plurality of unit pixels in the pixel region PXR. The chip pad 15 may include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), and the like, or a combination thereof.

The plurality of chip pads 15 may be connected with a substrate pad 25 of a package substrate 20, which will be described later, by a conductive bonding member 70. For example, as shown in FIG. 1, the image sensor 1 may be disposed on the package substrate 20, and may be electrically connected with the package substrate 20 through a conductive wire that connects the chip pad 15 and the substrate pad 25.

The pixel region PXR of the image sensor 1 may include a plurality of pixels. For example, the pixel region PXR may include a pixel array including unit pixels. For example, the plurality of unit pixels may be arranged in a 2-dimensional array.

Each of the plurality of unit pixels may include, for example, a photodiode sensing light, a transfer transistor transmitting charges generated by the photodiode, a floating diffusion region storing the transmitted charges, a reset transistor periodically resetting the floating diffusion region, and a source follower buffering a signal according to the charges charged in the floating diffusion region.

The pixel region PXR of the image sensor 1 may include an active pixel region PXR1 and a dark pixel region PXR2 at least partially surrounding the active pixel region PXR1. The actual composition of pixels in the active pixel region PXR1 and the dark pixel region PXR2 may be the same as each other. However, the dark pixel region PXR2 may be covered by a light blocking layer 40.

The light blocking layer 40 may have a shape at least partially surrounding the active pixel region PXR1 on a plane. For example, referring to FIG. 2, the light blocking layer 40 may have a ring shape as a whole.

The light blocking layer 40 may include an ink composition. The ink composition may include, for example, a low-molecular, polymer, or organic material. For example, the light blocking layer 40 may include a photosensitive material including a black color pigment.

According to an embodiment of the present inventive concept, the image sensor 1 includes a substrate structure 10, which structures are stacked on each other, and a plurality of penetration electrodes 150, which electrically connect the stacked structures to each other.

Referring to FIG. 1 and FIG. 2, the bonding structure BS may be disposed on the top surface of the plurality of penetration electrodes 150 of the image sensor 1 in the image sensor package 100. When top surfaces of the plurality of penetration electrode 150 are exposed, air may penetrate into the interface between each penetration electrode 150 and the substrate structure 10 due to the bonding structure BS, and thus, a defect may occur in the image sensor 1. To prevent this, a protective layer 13 may be disposed at the surface of the penetration electrode region BVR of the image sensor 1.

According to an embodiment of the present inventive concept, the image sensor 1 may include a protective layer 13 that is divided into a plurality of cells and covers the penetration electrode region BVR. According to an embodiment of the present inventive concept, the protective layer 13 may have a divided form. Accordingly, due to a difference in a coefficient of thermal expansion (CTE) of the substrate structure 10 and the protective layer 13 (which is interposed between the substrate structure 10 and the bonding structure BS with adherence), occurrence of cracks or break in the protective layer 13 can be prevented.

In addition, in this specification, a single part of the divided plurality of parts of the protective layer 13 is defined as a “cell” regardless of size. A detailed configuration of the protective layer 13 will be described later.

The bonding structure BS may be disposed on at least some regions of the protective layer 13.

The bonding structure BS is a portion for bonding other parts on the image sensor 1. According to an embodiment of the present inventive concept, the bonding structure BS may be disposed between the image sensor 1 and the transparent substrate 30.

The bonding structure BS may be provided on an upper surface of the peripheral region PDR of the image sensor 1. For example, the bonding structure BS may have an annular shape along the upper surface of the peripheral region PDR of the image sensor 1. The bonding structure BS may have a shape at least partially surrounding the pixel region PXR on a plane. A separation space may be formed between the image sensor 1 and the transparent substrate 30 by the bonding structure BS, and the inflow of external moisture or contaminant materials into the separation space may be prevented.

According to an embodiment of the present inventive concept, the bonding structure BS may overlap at least a part of the penetration electrode region BVR on a plane. The protective layer 13 may be disposed on the surface of the penetration electrode 150 in the region of the penetration electrode region BVR, overlapping the bonding structure BS. Accordingly, the protective layer 13 may contact the bonding structure BS in the region of the penetration electrode region BVR, overlapping the bonding structure BS.

According to an embodiment of the present inventive concept, as shown in FIG. 1, the bonding structure BS may include a bonding layer 60. The bonding layer 60 includes an annular shape along an upper surface of the peripheral region PDR of the image sensor 1 between the transparent substrate 30 and the image sensor 1, thereby bonding the transparent substrate 30 and the image sensor 1 to each other.

The bonding layer 60 may include glue, and, for example, may include epoxy resin or other bonding materials. According to an embodiment of the present inventive concept, the bonding layer 60 may be UV curable. For example, the bonding layer 60 is applied with an annular shape along the upper surface of the peripheral region PDR of the image sensor 1, and then, the bonding layer 60 is UV cured such that the transparent substrate 30 may be bonded to the image sensor 1 through the bonding layer 60. However, this is not restrictive, and the bonding layer 60 may have the property of changing shape fluidly by heat or pressure.

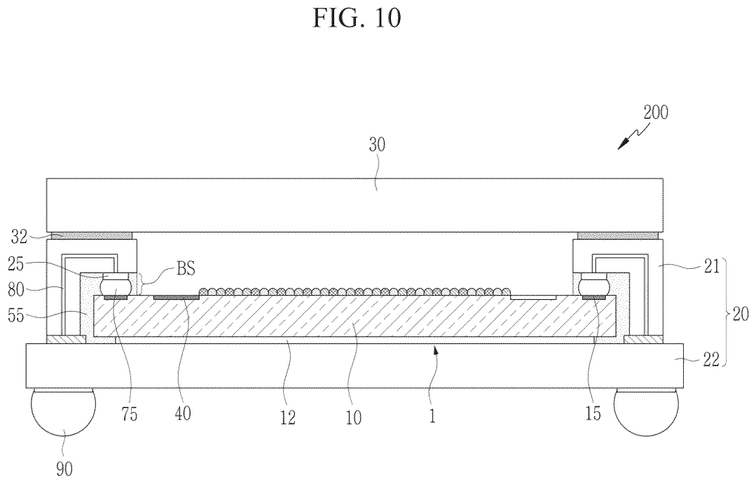

According to an embodiment of the present inventive concept, the bonding structure BS may include a bump (refer to FIG. 10) that electrically connects the image sensor 1 and the package substrate 20 to each other, and this feature will be described later.

The transparent substrate 30 is a portion through which light is transmitted, and may be formed of a transparent polymer material such as acryl, or glass.

The transparent substrate 30 may be disposed on the image sensor 1 at a distance therefrom, and may cover the image sensor 1. For example, a bottom surface of the transparent substrate 30 may be parallel with the upper surface of the image sensor 1, and the transparent substrate 30 may have substantially the same width and length as those of the image sensor 1. In addition, the transparent substrate 30 may have width and length larger or smaller than those of the image sensor 1.

The transparent substrate 30 may include an optical filter that may transmit or block light of a specific wavelength band. For example, the transparent substrate 30 may include an IR filter that filters infrared or near infrared rays.

The package substrate 20 is a portion that supports the image sensor 1, and the image sensor 1 is mounted thereon. In addition, the package substrate 20 is electrically connected with the image sensor 1.

Referring to FIG. 1, the package substrate 20 of an embodiment of the present inventive concept may be disposed in parallel with the image sensor 1 while supporting the image sensor 1. For example, the package substrate 20 may include a printed circuit board (PCB). However, this is not restrictive, and the package substrate 20 may include, for example, a ceramic leadless chip carrier (CLCC) and a plastic leaded chip carrier (PLCC). In addition, the package substrate 20 may include a redistribution layer formed of plurality of redistribution vias, a plurality of redistribution lines, and an insulation layer.

According to an embodiment of the present inventive concept, the package substrate 20 may have a width and a length that are larger than those of the image sensor 1. The substrate pad 25 may be provided on the upper surface of the package substrate 20.

An external connection terminal 90 may be provided on the bottom surface of the package substrate 20 to physically and electrically connect the image sensor package 100 to an external substrate and/or external device. The external connection terminal 90 may be electrically connected to the substrate pad 25 through electrical wiring provided inside the package substrate 20. For example, the external connection terminal 90 may be connected with a conductive pad provided in the bottom surface of the package substrate 20. The external connection terminal 90 may include solder, and, for example, may include a solder ball.

According to an embodiment of the present inventive concept, an encapsulant 50 may be disposed on the upper surface of the package substrate 20. The encapsulant 50 may encapsulate a side surface of the image sensor 1, a side surface of the transparent substrate 30, the bonding structure BS (or, e.g., an adhesive layer), and a conductive bonding member 70 (or, e.g., a conductive wire) on the upper surface of the package substrate 20. For example, the encapsulant 50 may be disposed on the side surface of the image sensor 1, the side surface of the transparent substrate 30, the bonding structure BS, and a conductive bonding member 70 on the upper surface of the package substrate 20.

The encapsulant 50 may include a molding compound, molding underfill, epoxy and/or resin, and may be, for example, an epoxy molding compounds (EMC).

The encapsulant 50 may cover the upper surface of the package substrate 20 while covering the side surfaces of the transparent substrate 30 such that the transparent substrate 30 may be exposed. For example, the encapsulant 50 may seal the side surfaces of the transparent substrate 30.

According to an embodiment of the present inventive concept, in the image sensor package 100, the protective layer 13, which is divided into a plurality of cells, cover the penetration electrode region BVR, and thus, damage to the protective layer 13 due to a difference in thermal expansion coefficient between the protective layer 13 and the substrate structure 10 can be prevented. Prior to describing the detailed configuration and characteristics of the protective layer 13, for convenience of understanding, the structure of the image sensor 1 according to an embodiment of the present inventive concept will first be described.

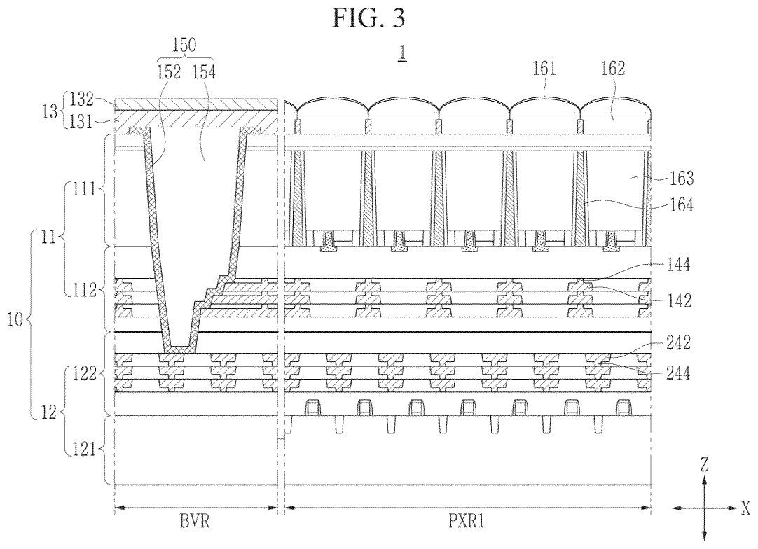

FIG. 3 is a schematic cross-sectional view of an image sensor in an image sensor package according to an embodiment of the present inventive concept. In FIG. 3, a part of the image sensor is illustrated for convenience of understanding. In FIG. 3, the right side shows a cross-sectional diagram of an active pixel region PXR1, and the left side shows a cross-sectional diagram of a penetration electrode region BVR. The image sensor 1 may further include the dark pixel region PXR2 and the peripheral region PDR shown in FIG. 1 and FIG. 2. In an embodiment of the present invention, the penetration electrode region BVR includes a plurality of penetration electrodes 150, but in FIG. 3, for better comprehension, only one penetration electrode 150 is illustrated; however, the present inventive concept is not limited thereto, and for example, more than one penetration electrode 150 may be provided. In the following description, one penetration electrode 150 will be described, but the same description can be applied to the plurality of penetration electrodes 150.

Referring to FIG. 3, the image sensor 1 may further include a substrate structure 10, the penetration electrode 150, and a protective layer 13.

According to an embodiment of the present inventive concept, the substrate structure 10 may be formed of a stacked structure in which a first structure 11 and a second structure 12 are bonded to each other, and in the penetration electrode region BVR, the penetration electrode 150 penetrates the first structure 11 and may extend into the second structure 12. The protective layer 13 may cover the penetration electrode region BVR on the substrate structure 10.

The first structure 11 is a structure in which a plurality of pixels are disposed, and as described above, has a pixel region PXR and the penetration electrode region BVR on a plane.

The first structure 11 may include a first side (upper surface in FIG. 3) and a second side (bottom surface in FIG. 3) that are opposite to each other. The first structure 11 may include a first substrate 111, which is disposed in the first side, and a second distribution structure 112, which is disposed in the second side. For example, the first side of the first structure 11 may correspond to a top surface of the first substrate 111, and the second side of the first structure 11 may correspond to a bottom surface of the second distribution structure 112.

The first substrate 111 may be formed of a semiconductor substrate, for example, a silicon substrate or an organic plastic substrate. A plurality of pixel separation layers 164 may be disposed in the first substrate 111, and a plurality of unit pixels 163 may be defined by the pixel separation layer 164. A color filter array 162 may be disposed on one side of the first substrate 111, and a micro lens array 161 may be disposed on the color filter array 162.

The color filter array 162 may include a plurality of color filters. The plurality of color filters may include, for example, a red (R) filter, a blue (B) filter, and a green (G) filter. For example, the plurality of color filters may include a cyan (C) filter, a yellow (Y) filter, and a magenta (M) filter. A color filter including one of R filter, B filter and/or G filter, or one of C filter, Y filter and/or M filter may be disposed on each of the plurality of unit pixels 163. The plurality of unit pixels 163 may recognize one color by detecting components of each separated incident light.

The micro lens array 161 may include, for example, a plurality of hemispherical micro lenses. The plurality of micro lenses may focus light, which is incident on the pixel region PXR, to the plurality of unit pixels 163.

The first distribution structure 112 may include a plurality of first distribution layers. For example, the first distribution structure 112 may have a structure in which a plurality of first distribution layers are stacked on each other. Each of the plurality of first distribution layers may include a plurality of first distribution patterns 142 and a plurality of first distribution vias 144.

The second structure 12 is a structure where a driving circuit, which drives the plurality of pixels 163, is disposed, and may be stacked on the second side of the first structure 11. The second structure 12 may include a third side (e.g., an upper surface in FIG. 3) and a fourth side (e.g., a bottom surface in FIG. 3) that are opposite to each other. The second structure 12 may include a second substrate 121, which is disposed on the fourth side, and a second distribution structure 122, which is disposed on the third side.

The second substrate 121 may be formed of a semiconductor substrate, for example, a silicon substrate or an organic plastic substrate. The second substrate 121 may include a driving circuit that drives a plurality of pixels 163 disposed in the first substrate 111. For example, the driving circuit may include transistors that are disposed in the second structure 12, and the transistors may be electrically connected to the second distribution vias 244 and the second distribution pattern 242. For example, the transistors may be electrically connected to the plurality of pixels 163 through wiring.

The second distribution structure 122 may include a plurality of second distribution layers electrically connected with the driving circuit. For example, the second distribution structure 122 may have a structure in which the plurality of second distribution layers are stacked on each other. Each of the plurality of second distribution layers may include a plurality of second distribution patterns 242 and a plurality of second distribution vias 244.

The penetration electrode 150 is a portion that electrically connects the first structure 11 and the second structure 12 to each other. According to an embodiment of the present inventive concept, penetration electrode 150 may extend from a surface of substrate structure 10 to a predetermined depth within an interior of the substrate structure 10. For example, the penetration electrode 150 may penetrate the first structure 11 at the surface (e.g., the first side) of the first structure 11 and may extend to a predetermined depth of the second structure 12. For example, referring to FIG. 3, the penetration electrode 150 may be connected to a plurality of first distribution layers and a plurality of second distribution layers.

The penetration electrode 150 may include a penetration electrode layer 152 and an insulation layer 154. The penetration electrode layer 152 may cover an inner surface of an electrode trench that is formed in the substrate structure 10, and the insulation layer 154 may fill the penetration electrode trench.

The penetration electrode layer 152 may be made of a metal material such as titanium, titanium nitride, tantalum, tantalum nitride, titanium tungsten, tungsten, aluminum, cobalt, nickel, or copper, or an alloy material including the same. In an embodiment of the present inventive concept, the penetration electrode layer 152 may be formed by a chemical vapor deposition (CVD) process, or an atomic layer deposition (ALD) process. For example, the penetration electrode layer 152 may have a thickness of about 2 μm to about 4 μm.

The penetration electrode layer 152 may be disposed on the first distribution pattern 142 of the first distribution structure 112 and the second distribution pattern 242 of the second distribution structure 122. The penetration electrode layer 152 may contact and be electrically connected to the first distribution pattern 142 of the first distribution structure 112. In addition, the penetration electrode layer 152 may contact and be electrically connect to the second distribution pattern 242 of the second distribution structure 122. In an embodiment of the present inventive concept, a side surface of the penetration electrode layer 152 may have a staircase shape to be connected to a plurality of distribution layers.

The insulation layer 154 may be formed of an insulating material such as silicon oxide, silicon nitride, and the like. In an embodiment of the present inventive concept, the insulation layer 154 may include tetraethyl orthosilicate (TEOS) or plasma enhanced-TEOS (PE-TEOS).

The protective layer 13 is a layer that covers the penetration electrode region BVR on the substrate structure 10. The protective layer 13 may cover an upper surface of the penetration electrode 150, which is exposed through the surface of the substrate structure 10.

The protective layer 13 may include a first protective layer 131 and a second protective layer 132. The first protective layer 131 may be disposed on the substrate structure 10, and the second protective layer 132 may be disposed on the first protective layer 131. The first protective layer 131 may be a layer corresponding to the color filter array 162 of the pixel region PXR. For example, the first protective layer 131 and the color filter array 162 may be disposed on the same layer as each other. For example, the first protective layer 131 may be made of the same material as the color filter array 162. For example, the first protective layer 131 may include an organic material. The second protective layer 132 may be a layer corresponding to the micro lens array 161 of the pixel region PXR. For example, the second protective layer 132 and the micro lens array 161 may be disposed on the same layer as each other. The second protective layer 132 may include a glass material (SiO₂).

The protective layer 13 and the substrate structure 10 may be different from each other with regard to thermal expansion coefficients. Since the protective layer 13 is disposed between the substrate structure 10 and the bonding structure BS, a crack may be formed in the protective layer 13 or the protective layer 13 may be damaged. To solve such a problem, according to an embodiment of the present inventive concept, the protective layer 13 may be divided into a plurality of cells. The protective layer 13 that is divided into the plurality of small cells has a smaller contact area with the bonding structure BS compared to an undivided protective layer, and thus, the stress can be dispersed during deformation that is caused by heat.

Hereinafter, the features of the protective layer 13 in the image sensor package 100 of an embodiment of the present inventive concept will be described in more detail.

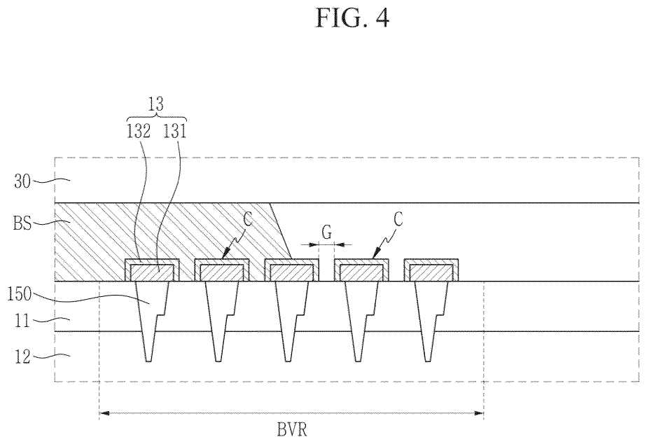

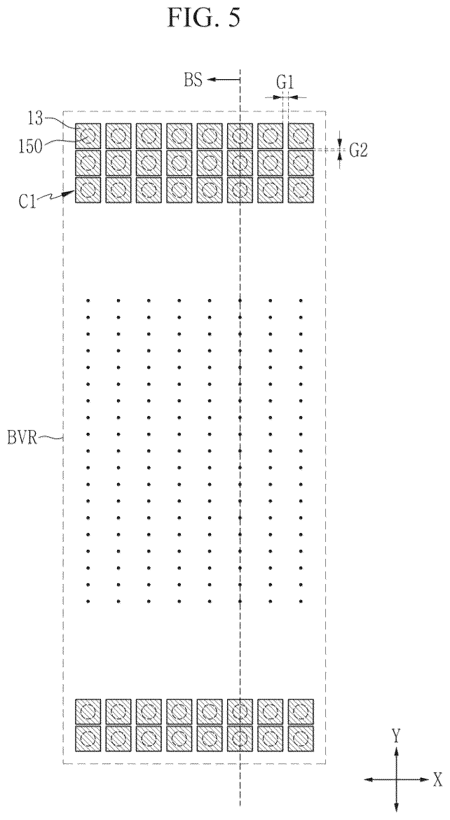

FIG. 4 is an enlarged view of the portion C of FIG. 1, and FIG. 5 is a schematic top plan view of the penetration electrode region in the image sensor package according to an embodiment of the present inventive concept. In FIG. 4 and FIG. 5, the number of penetration electrodes is arbitrarily drawn, and therefore the number of penetration electrodes is not limited to the drawing.

Referring to FIG. 4 and FIG. 5, the protective layer 13 includes a plurality of cells C. The plurality of cells C may cover an exposed surface (e.g., an upper surface) of the plurality of penetration electrodes 150. Each of the plurality of cells C may cover an upper surface of at least one of the plurality of penetration electrodes 150. For example, each of the plurality of cells C may cover an upper surface of one penetration electrode 150, or each of the plurality of cells C may cover upper surfaces of two or more penetration electrodes 150. The plurality of cells C may be arranged spaced apart from each other by a predetermined distance G.

For convenience in understanding, in the present specification, a cell C covering an upper surface of one penetration electrode 150 is called a first cell C1 and a cell C covering upper surfaces of two or more penetration electrodes 150 are called second cells C2.

According to an embodiment of the present inventive concept, as shown in FIG. 4, at least a part of the plurality of cells C may be disposed between the bonding structure BS and the first structure 11. According to an embodiment of the present inventive concept, unlike what is shown in FIG. 4, the plurality of cells C may be disposed entirely between the bonding structure BS and the first structure 11.

Referring to FIG. 5, the plurality of cells may include a plurality of first cells C1 covering upper surfaces of the plurality of penetration electrodes 150. For example, each first cell C1 may cover an upper surface of one penetration electrode 150.

In this case, the first cell C1 may cover the entire upper surface of the penetration electrode 150. For example, on a plane, the first cell C1 is larger than the upper surface of the penetration electrode 150 in size such that the upper surface of the penetration electrode 150 can be disposed in the area of the first cell C1. For example, on a plane, the penetration electrode 150 may be disposed in a footprint of the first cell C1. Accordingly, the first cell C1 may cover an interface between the penetration electrode 150 and the substrate structure 10 (or first structure 11).

The plurality of first cells C1 may be spaced apart from each other by a predetermined interval. Referring to FIG. 5, the plurality of first cells C1 may be spaced apart by a first gap G1 in the X direction and by a second gap G2 in the Y direction. Here, the first gap G1 and the second gap G2 may be equal to or different from each other.

In FIG. 5, the penetration electrode 150 is formed in the shape of a circle, and the first cell C1 of the protective layer 13 is formed in the shape of a quadrangle on a plane, but the shapes of the penetration electrode 150 and first cell C1 are not limited thereto.

In the present embodiment, the first cell C1 may have a shape corresponding to the shape of the upper surface of the penetration electrode 150 on a plane. For example, the upper surface of the penetration electrode 150 can have various shapes such as a circular shape, an elliptical shape, a polygonal shape, and the like on a plane, and the first cell C1 may also have a corresponding shape such as a circular shape, an elliptical shape, a polygonal shape, and the like.

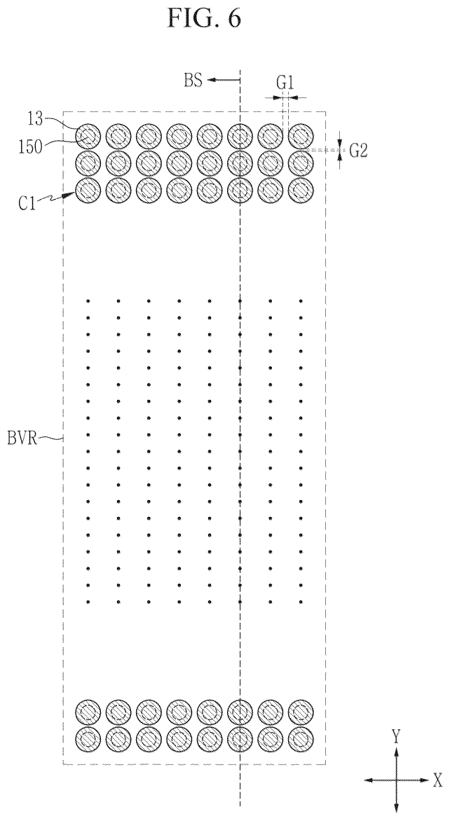

FIG. 6 shows another shape of the protective layer 13. Referring to FIG. 6, on a plane, the upper surface of the penetration electrode 150 is circular, and the first cell C1 is also circular. The plurality of circular first cells C1 may be spaced apart by a first gap G1 in the X direction and spaced apart by a second gap G2 in the Y direction. Here, the first gap G1 and the second gap G2 may be the same or different.

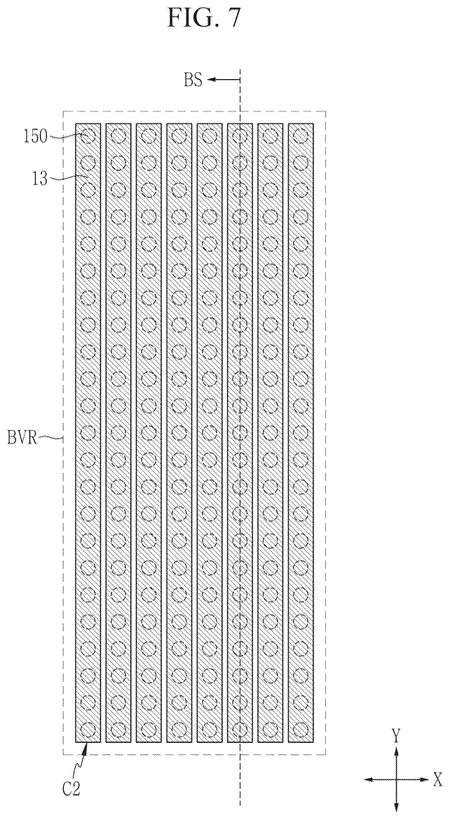

Hereinafter, numerous variations of the protective layer 13 will be described. FIG. 7 to FIG. 9 shows another shape of the protective layer 13.

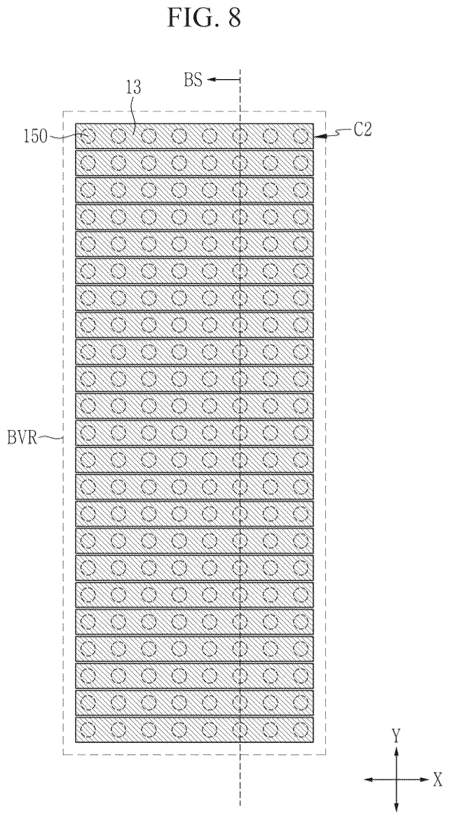

Referring to FIG. 7 and FIG. 8, a plurality of cells may include a plurality of second cells C2 covering upper surfaces of at least two of the plurality of penetration electrodes 150. In addition, each of the plurality of second cells C2 may cover the entire upper surfaces of at least two of the plurality of penetration electrodes 150.

For example, each of the second cells C2 may be formed in the shape of a bar or rectangle extending in one direction on a plane to cover upper surfaces of two or more adjacent penetration electrodes 150.

Referring to FIG. 7, each second cell C2 may have a shape extending in a long direction (e.g., the Y direction) of the penetration electrode region BVR. In this case, the protective layer 13 may include a plurality of second cells C2 that are disposed in parallel with each other at a distance from each other.

Referring to FIG. 8, each second cell C2 may have a shape extending in a short direction (e.g., the X direction) of the penetration electrode region BVR. In this case, the protective layer 13 may include a plurality of second cells C2 that are disposed in parallel with each other at a distance from each other.

According to an embodiment of the present inventive concept, the plurality of cells C may include a plurality of types of cells, and each type of cell may cover a different number of penetration electrodes 150.

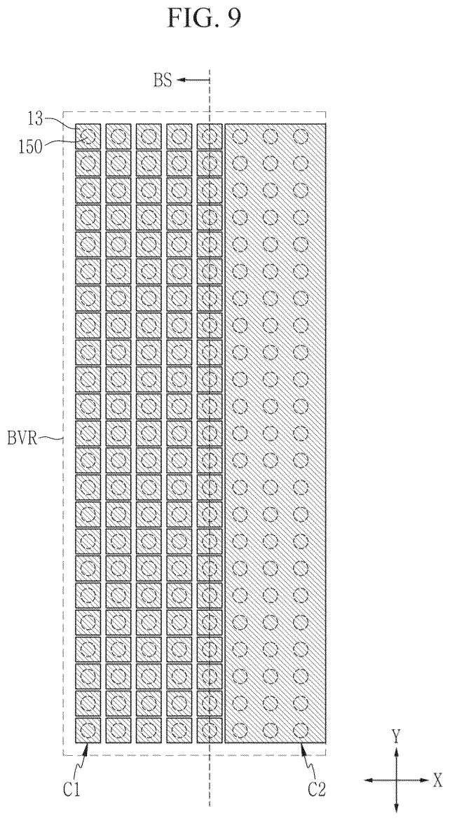

Referring to FIG. 9, a plurality of cells C may include a first cell C1, which covers an upper surface of one of a plurality of penetration electrodes 150, and a second cell C2, which covers upper surfaces of two or more penetration electrodes 150. For example, a plurality of first cells C1 may be arranged in an area of the penetration electrode region BVR, overlapping the bonding structure BS, and a plurality of cells C2 may be arranged in an area of the penetration electrode region BVR, not overlapping the bonding structure BS. In FIG. 9, the second cell C2 is shown to cover all the penetration electrodes 150 in the remaining region of the penetration electrode region BVR except for the first cell C1, but the present inventive concept is not limited thereto.

The smaller the protective layer 13 is divided (e.g., the more it is divided, the smaller the cells will be), the more stress transferred during thermal deformation can be dispersed. Correspondingly, as shown in FIG. 5 and FIG. 6, the stress distribution effect can be increased when the protective layer 13 is divided into a plurality of first cells C1. However, a manufacturing process of the protective layer 13 may be difficult. As shown in FIG. 7 and FIG. 8, the stress dissipation effect may be low, but the manufacturing process of the protective layer 13 may be easier in the case where the protective layer 13 is divided into a plurality of second cell C2 than in the case where the protective layer 13 is divided into a plurality of first cell C1. As shown in FIG. 9, when the protective layer 13 is divided into a plurality of first and second cells C1 and C2, it is possible to facilitate the manufacturing process of the protective layer 13 while increasing the stress dissipation effect by disposing the plurality of first cell C1 in a region overlapping the bonding structure BS.

In addition, in the above description, a wire bonding type image sensor package has been described as an example, but the above-described characteristics may be equally applied to a flip chip type image sensor package.

FIG. 10 is a cross-sectional view of an image sensor package according to an embodiment of the present inventive concept, and illustrates a flip chip type image sensor package 200. Descriptions of the same contents as the image sensor package 100 of the embodiment described above are omitted or briefly discussed, and only other contents are described.

Referring to FIG. 10, a package substrate 20 may include a connection substrate 21 and a base substrate 22.

The connection substrate 21 may have an opening to expose a pixel region PXR of an image sensor 1, and may have a shape at least partially surrounding a top edge and a side surface of the image sensor 1. An expansion opening having an expansion opening such that the image sensor 1 can be inserted therein may be provided under the connection substrate 21. In addition, the connection substrate 21 may have a form in which two cavities may be formed. The connection substrate 21 may include a printed circuit board (PCB) formed of, for example, a ceramic material.

A transparent substrate 30 may be attached via a first adhesive member 32 onto the connection substrate 21.

A substrate pad 25 may be provided on a lower surface of the connection substrate 21. For example, the substrate pad 25 may be disposed facing the chip pad 15 of the image sensor 1.

According to an embodiment of the present inventive concept, a conductive bonding member 75, which connects between the chip pad 15 and the substrate pad 25, may include a bump. For example, the conductive bonding member 75 may include Au bumps formed by Au—Au bonding.

According to an embodiment of the present inventive concept, the conductive bonding member 75 may be sealed by an encapsulant 55. As shown in FIG. 10, a space between the conductive bonding member 75, the image sensor 1, and the connection substrate 21 may be filled with the encapsulant 55. For example, the encapsulant 55 may be disposed on the conductive bonding member 75, the image sensor 1, and the connection substrate 21. For example, the encapsulant 55 may include an underfill.

In addition, in the present embodiment, a bonding structure BS may include the above-described conductive bonding member 75 and the encapsulant 55 filling a space between the image sensor 1 and the connection substrate 21.

Even in the present embodiment, the bonding structure BS may overlap at least a part of a penetration electrode region BVR on a plane. In addition, a protective layer 13 that is divided into a plurality of cells may cover the penetration electrode region BVR. Accordingly, at least a part of the divided plurality of cells may be interposed between the substrate structure 10 and the bonding structure BS.

The aforementioned connection substrate 21 may be electrically and physically coupled to the base substrate 22. According to an embodiment of the present inventive concept, the connection substrate 21 may include a conductive line 80 electrically connecting the substrate pad 25 and a base substrate 22 to each other.

The base substrate 22 may be disposed below the image sensor 1, and may support the image sensor 1. For example, the image sensor 1 may be fixed to the base substrate 22 via the second adhesive member 12.

A wiring line electrically connected to the aforementioned conductive line 80 may be included inside the base substrate 22. In this case, the wiring line may be electrically connected to an external connection terminal 90.

While the present inventive concept has been shown and described with reference to the embodiments thereof, it will be apparent to those of ordinary skill in the art that various changes in form and detail may be made thereto without departing from the spirit and scope of the present inventive concept.

What is claimed is:

1. An image sensor comprising:
a first structure including a first side, a second side opposite to the first side, a pixel region where a plurality of pixels are disposed, and a penetration electrode region disposed adjacent to the pixel region;
a second structure in which a driving circuit for driving the plurality of pixels is disposed, and stacked on the second side of the first structure;
a plurality of penetration electrodes that penetrate the first structure and the second structure to electrically connect the first structure and the second structure to each other, and are disposed in the penetration electrode region; and
a protective layer that is disposed on the plurality of penetration electrodes, and divided into a plurality of cells, wherein the protective layer covers the penetration electrode region.

2. The image sensor of claim 1, wherein:
each of the plurality of cells covers an upper surface of at least one of the plurality of penetration electrodes.

3. The image sensor of claim 1, wherein:
the plurality of cells are separated from each other.

4. The image sensor of claim 1, wherein:
the protective layer comprises a first protective layer and a second protective layer, wherein the first protective layer is disposed on the first side of the first structure, and the second protective layer is disposed on the first protective layer.

5. The image sensor of claim 1, wherein:
the first structure comprises:
a first substrate disposed on the first side and provided with a micro lens array; and
a first distribution structure disposed on the second side and including a plurality of first distribution layers.

6. The image sensor of claim 5, wherein:
the second structure comprises:
a second distribution structure including a plurality of second distribution layers and stacked on the first distribution structure; and
a second substrate disposed on the second distribution structure.

7. The image sensor of claim 6, wherein:
the plurality of penetration electrodes connect the plurality of first distribution layers to the plurality of second distribution layers.

8. An image sensor package comprising:
an image sensor comprising a substrate structure including a pixel region and a penetration electrode region, wherein a plurality of pixels are disposed in the pixel region, and the penetration electrode region is disposed adjacent to the pixel region, and wherein the image sensor further includes a protective layer that covers the penetration electrode region on the substrate structure; and
a bonding structure that is disposed on the image sensor and at least partially surrounds the pixel region while overlapping at least a part of the penetration electrode region,
wherein a plurality of penetration electrodes are disposed in the penetration electrode region, and extend a predetermined depth into the substrate structure from a surface of the substrate structure,
wherein the protective layer is divided into a plurality of separated cells and covers surfaces of the plurality of penetration electrodes, and at least a part of the plurality of cells is disposed between the bonding structure and the substrate structure.

9. The image sensor package of claim 8, wherein:
the substrate structure and the protective layer have different coefficients of thermal expansion (CTE) from each other.

10. The image sensor package of claim 8, further comprising a transparent substrate spaced apart from the bonding structure and covering the image sensor.

11. The image sensor package of claim 8, wherein:
each of the plurality of cells covers an upper surface of at least one of the plurality of penetration electrodes.

12. The image sensor package of claim 8, wherein:
the plurality of cells comprise a plurality of first cells covering upper surfaces of the plurality of penetration electrodes, respectively, and
each of the plurality of first cells covers the entire upper surface of each of the plurality of penetration electrodes, respectively.

13. The image sensor package of claim 12, wherein:
each of the plurality of first cells has a shape that corresponds to the shape of the upper surface of each of the plurality of penetration electrodes.

14. The image sensor package of claim 8, wherein:
the plurality of cells comprise a plurality of second cells covering upper surfaces of at least two of the plurality of penetration electrodes, and
each of the plurality of second cells covers an entirety of the upper surfaces of the at least two of plurality of penetration electrodes.

15. The image sensor package of claim 14, wherein:
each of the plurality of second cells has a shape extending in a short side direction or a long side direction of the penetration electrode region.

16. The image sensor package of claim 8, wherein:
the plurality of cells comprise a plurality of types of cells, wherein each type of cell has a different number of cells covering the penetration electrodes.

17. The image sensor package of claim 8, wherein:
a first structure and a second structure are stacked on each other in the substrate structure, wherein the first structure is provided with a plurality of pixels, and the second structure is provided with a driving circuit driving the plurality of pixels.

18. An image sensor package comprising:
an image sensor including a pixel region, a penetration electrode region, a substrate structure, and a protective layer, wherein a plurality of pixels are disposed in the pixel region, wherein the penetration electrode region disposed adjacent to the pixel region, wherein the substrate structure includes a first structure and a second structure, wherein the first structure has a plurality of pixels disposed in an upper portion of the first structure, wherein the second structure has a driving circuit for driving the plurality of pixels, and wherein the protective layer covers the penetration electrode region;
a transparent substrate that is disposed above the image sensor; and
a bonding structure that is disposed between the image sensor and the transparent substrate, and at least partially surrounds the pixel region, wherein the bonding structure partially overlaps at least a part of the penetration electrode region,
wherein a plurality of penetration electrodes are disposed in the penetration electrode region, and extend a predetermined depth into the second structure while penetrating the first structure from a surface of the first structure, and
wherein the protective layer is divided into a plurality of cells and covers surfaces of the plurality of penetration electrodes, and at least a part of the plurality of cells is disposed between the bonding structure and the first structure.

19. The image sensor package of claim 18, further comprising:
a package substrate disposed on the image sensor, wherein an external connection terminal is disposed on the package substrate; and
a conductive bonding member that electrically connects the image sensor and the package substrate to each other.

20. The image sensor package of claim 18, further comprising a package substrate including an opening through which the pixel region is exposed, and at least partially surrounding a top edge and a side surface of the image sensor,
wherein, in the bonding structure, a bump electrically connects the image sensor and the package substrate to each other.
